(19) United States
(12) Patent Application Publication
(10) Pub. No.: US 2026/0093881 A1
(43) Pub. Date: Apr. 2, 2026

(54) CASCADED LOOKUP-TABLE MAPPING FOR CIRCUIT DESIGN AND IMPLEMENTATION

(71) Applicant: Xilinx, Inc., San Jose, CA (US)

(72) Inventors: Fan Zhang, San Jose, CA (US); Yen Hsi Lin, San Jose, CA (US); Aman Gayasen, San Jose, CA (US)

(73) Assignee: Xilinx, Inc., San Jose, CA (US)

(21) Appl. No.: 18/899,599

(22) Filed: Sep. 27, 2024

(51) Int. Cl. G06F 30/327; G06F 1/03

(52) U.S. Cl. CPC G06F 30/327; G06F 1/03

(57) ABSTRACT

Computer-implemented technology mapping of a circuit design includes, for a node of a circuit design, generating a plurality of regular cuts and a plurality of super cuts. A regular cut subset that is a subset of the plurality of regular cuts having M highest priorities and a super cut subset that is a subset of the plurality of super cuts having N highest priorities are generated. Each super cut that is incompatible with a cascaded lookup-table (LUT) circuit structure is discarding from the super cut subset. A cut from a group of cuts including the regular cut subset and the super cut subset is selected to implement a portion of the circuit design including the node.

### TECHNICAL FIELD

This disclosure relates to integrated circuits (IC) devices and, more particularly, to implementing circuit designs in an IC device that includes cascaded lookup-table circuit structures.

### BACKGROUND

A lookup-table (LUT) is a type of primitive that is commonly available within integrated circuit (IC) devices that is used to implement combinatorial logic. LUTs are a type of programmable circuitry available within a variety of different types of IC devices including programmable IC devices. A LUT primitive will have some number of inputs “k”and is capable of implementing any k-input function.

In implementing a circuit design within a modern IC device, routing delays, also referred to as “interconnect delays,” have become a significant concern. Routing delays are often a limiting factor for Quality-of-Result (QoR) as may be quantified in terms of maximum operating frequency or speed of the circuit design and/or the combinatorial logic as physically realized in an IC device. These routing delays include delays incurred on interconnects that join LUTs.

### SUMMARY

In one or more embodiments, a computer-implemented method of technology mapping a circuit design includes generating a plurality of regular cuts and a plurality of super cuts for a node of a circuit design. The method includes generating, by the computer hardware, a regular cut subset that is a subset of the plurality of regular cuts having M highest priorities and a super cut subset that is a subset of the plurality of super cuts having N highest priorities. The method includes discarding, by the computer hardware, from the super cut subset each super cut that is incompatible with a cascaded lookup-table (LUT) circuit structure. The method includes selecting a cut from a group of cuts including the regular cut subset and the super cut subset to implement a portion of the circuit design including the node.

In one or more embodiments, a system includes a memory capable of storing program instructions and a hardware processor capable of performing operations for mapping a circuit design in response to execution of the program instructions. The operations include generating a plurality of regular cuts and a plurality of super cuts for a node of a circuit design. The operations include generating a regular cut subset that is a subset of the plurality of regular cuts having M highest priorities and a super cut subset that is a subset of the plurality of super cuts having N highest priorities. The operations include discarding from the super cut subset each super cut that is incompatible with a cascaded LUT circuit structure. The operations include selecting a cut from a group of cuts including the regular cut subset and the super cut subset to implement a portion of the circuit design including the node.

In one or more embodiments, a computer program product includes a computer readable storage medium having program instructions embodied therewith. The program instructions are executable by computer hardware, e.g., a hardware processor, to cause the computer hardware to execute operations. The operations include generating a plurality of regular cuts and a plurality of super cuts for a node of a circuit design. The operations include generating a regular cut subset that is a subset of the plurality of regular cuts having M highest priorities and a super cut subset that is a subset of the plurality of super cuts having N highest priorities. The operations include discarding from the super cut subset each super cut that is incompatible with a cascaded LUT circuit structure. The operations include selecting a cut from a group of cuts including the regular cut subset and the super cut subset to implement a portion of the circuit design including the node.

This Summary section is provided merely to introduce certain concepts and not to identify any key or essential features of the claimed subject matter. Many other features and embodiments of the disclosed technology will be apparent from the accompanying drawings and from the following detailed description.

### BRIEF DESCRIPTION OF THE DRAWINGS

The accompanying drawings show one or more embodiments of the disclosed technology. The drawings, however, should not be construed to be limiting of the inventive arrangements to only the embodiments shown. Various aspects and advantages will become apparent upon review of the following detailed description and upon reference to the drawings.

FIG. 1 illustrates an example of a lookup-table (LUT) primitive of a target integrated circuit (IC) device having cascaded connections in accordance with one or more embodiments of the disclosed technology.

FIG. 2 illustrates example LUT circuitry where cascaded connections are not utilized within a target IC device.

FIG. 3 illustrates example LUT circuitry that utilizes a cascaded connection within the target IC device in accordance with one or more embodiments of the disclosed technology.

FIG. 4 illustrates a method of processing a circuit design for implementation in a target IC device in accordance with one or more embodiments of the disclosed technology.

FIG. 5 illustrates a method of detecting compatibility of a super cut with a cascaded LUT circuit structure in accordance with one or more embodiments of the disclosed technology.

FIG. 6 illustrates a super cut including a qualified free-set cut in accordance with one or more embodiments of the disclosed technology.

FIG. 7 illustrates a super cut including a qualified free-set cut and a qualified bound-set cut in accordance with one or more embodiments of the disclosed technology.

FIG. 8 illustrates an example of a data processing system for use with one or more embodiments of the disclosed technology.

### DETAILED DESCRIPTION

While the disclosure concludes with claims defining novel features, it is believed that the various features described within this disclosure will be better understood from a consideration of the description in conjunction with the drawings.

The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (IC) devices and, more particularly, to implementing circuit designs in an IC device that includes cascaded lookup-table (LUT) circuit structures. Routing delays are a significant concern when implementing a circuit design in an IC device as such delays can be a limiting factor for Quality-of-Result (QoR) as quantified in terms of maximum operating frequency or speed of the circuit design and/or combinatorial logic as physically realized in an IC device.

Because routing delays include LUT-to-LUT interconnection delays, some IC devices have begun to incorporate faster LUT-to-LUT connections. These faster connections, referred to herein as “cascaded connections,” are often implemented or available only between selected LUTs. This requires that the Electronic Design Automation (EDA) tool be aware of the availability of cascaded connections in a given IC device, the requirements for using such circuit structures, and be able to pro-actively adapt the circuit design to utilize the cascaded connections. Often, the EDA tool is unable to adequately leverage these faster cascaded connections resulting in a physically realized circuit design having a reduced QoR in terms of maximum operating frequency and/or slower operation of combinatorial circuitry.

In accordance with the inventive arrangements described herein, methods, systems, and computer program products are described that are capable of leveraging usage of cascaded connections between LUTs when processing a circuit design for implementation in an IC device equipped with such circuit structures. The inventive arrangements may be utilized, for example, as part of a technology mapping process that takes a technology independent circuit design and transforms that representation into a technology specific circuit design.

For purposes of illustration, a typical LUT-to-LUT interconnect delay may range from approximately 120 picoseconds to approximately 150 picoseconds. In some cases, the LUT-to-LUT interconnection delay may be as large as a nanosecond. By comparison, a cascaded connection between two LUTs may have an interconnect delay as low as 19 picoseconds, providing markedly improved performance relative to a standard or typical LUT-to-LUT interconnect.

The inventive arrangements are capable of performing technology mapping for circuit designs in a manner that increases the utilization of cascaded LUT circuit structures of a particular IC device referred to herein as the “target IC device.” The circuit design, as technology mapped for implementation in the target IC device, will utilize cascaded LUT circuit structures to a greater extent than would otherwise have been the case using conventional technology mapping techniques thereby realizing greater QoR in terms of maximum operating frequency and/or speed of combinatorial logic with the circuit design physically realized within the target IC device.

In one or more embodiments, the inventive arrangements are capable of increasing the options for performing technology mapping by ensuring that various cuts are generated that are specifically suited for technology mapping into cascaded LUT circuit structures. While providing these additional options, the inventive arrangements provide efficient memory management and storage options that facilitate processing of various types of cuts for large circuit designs, e.g., graphs, to prevent runtime from growing unmanageably long while increasing the QoR in the technology mapping process. The inventive arrangements also provide a structural detection technique that is capable of determining whether a given cut is compatible with cascaded LUT circuit structures and doing so in a way that is faster and less computationally intensive than other techniques such as decomposition.

Accordingly, the inventive arrangements are capable of utilizing hardware features such as cascaded LUT circuit structures and packing logic of a circuit design compactly to improve performance (e.g., speed) of the fabric, also referred to herein as programmable circuitry (e.g., programmable logic). The inventive arrangements are capable of achieving a success rate for technology mapping functions onto cascaded LUT circuit structures that is higher than conventional techniques. The inventive arrangements are capable of achieving a success rate for technology mapping functions onto cascaded LUT circuit structures that is higher than conventional techniques are able to handle a large number of implementation choices (e.g., cuts) with prioritization to reduce runtime while achieving improved QoR. Further, the embodiments disclosed herein may be expanded to explore new fabric architectures in different types of IC devices including programmable circuitry (e.g., programmable logic) including yet to be developed IC devices and/or programmable circuitry architectures.

Further aspects of the inventive arrangements are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

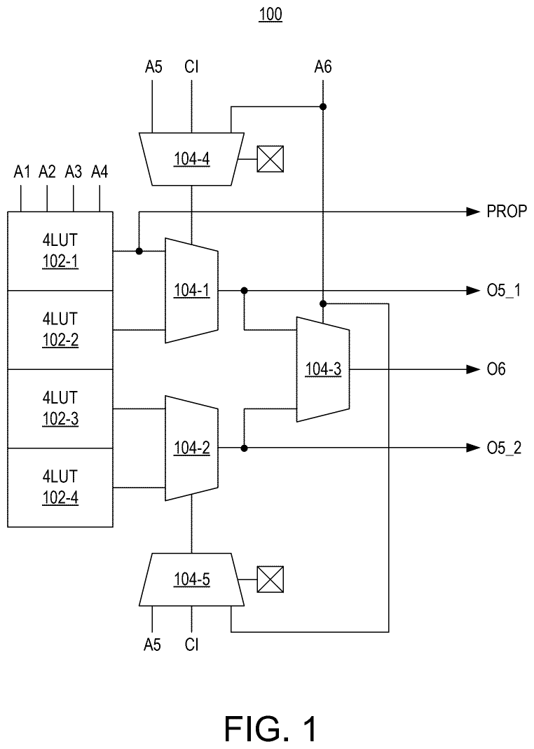

FIG. 1 illustrates an example of a LUT primitive 100 of a target IC device having cascaded connections in accordance with one or more embodiments of the disclosed technology. In general, the target IC device may include programmable circuitry such as programmable logic that includes one or more LUT primitives 100. An example of the target IC device may be a Field Programmable Gate Array (FPGA) or any other IC that includes programmable circuitry such as programmable logic. In the example of FIG. 1, LUT primitive 100 is a 6-input LUT capable of receiving input signals A1, A2, A3, A4, A5, and A6. LUT primitive 100 includes a plurality of 4-input LUTS shown as 4LUTs 102 (e.g., 4LUTs 102-1, 102-2, 102-3, and 102-4). In the example, LUT primitive 100 further includes switches 104 (e.g., switches 104-1, 104-2, 104-3, 104-4, and 104-5).

LUT primitive 100 is capable of generating a plurality of different outputs shown as PROP, O5_1, O6, and O5_2. In the example, the PROP signal is used for carry logic and is not visible external to the circuit structure in which LUT primitive 100 may be disposed, e.g., a configurable logic block. The output signal O6 may be fed to the cascade in (CI) of switch 104-4 or switch 104-5 of another LUT primitive in the same cascaded LUT circuit structure. In the example, switch 104-4 and switch 104-5 may be programmed to pass either the input signal A5 or the signal present at cascade input CI. In one or more examples, switch 104-4 and switch 104-5 may default to passing input signal A5.

In one or more embodiments, the target IC device includes a plurality of configurable logic blocks (CLBs), where one or more selected CLBs or each CLB includes two or more LUT primitives 100 forming a cascaded LUT circuit structure.

Within this disclosure, a cascaded LUT circuit structure refers to two or more LUT primitives that are connected by cascaded connection(s). A cascaded connection is a connection that directly connects an output of a LUT primitive with an input of another LUT primitive.

For purposes of illustration and not limitation, some CLBs may include multiple slices or regions with each region including up to eight LUT primitives 100. The LUT primitives 100 of different slices do not have cascaded connections. As such, each CLB is capable of implementing two different cascaded LUT circuit structures each with up to eight cascaded LUT primitives.

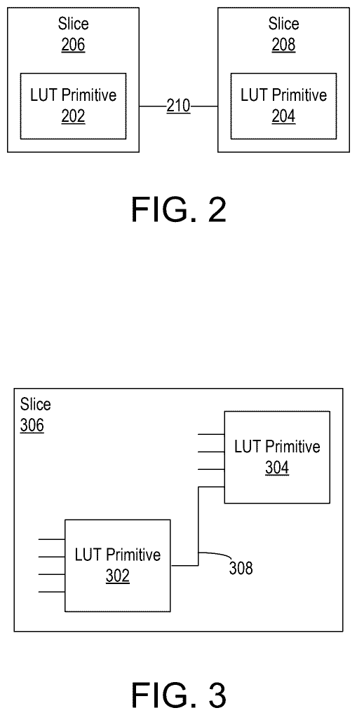

FIG. 2 illustrates example LUT circuitry where cascaded connections are not utilized within a target IC device. In the example of FIG. 2, a portion of a circuit design has been technology mapped and placed into LUT primitive 202 and LUT primitive 204 of the target IC device. As shown, LUT primitive 202 is disposed in a slice 206 and LUT primitive 204 is disposed in a slice 208. Slices 206, 208 may be disposed in a same CLB or in two different CLBs.

In the case where LUT primitives 202 and 204 are implemented as described in connection with FIG. 2, being disposed in different slices, a cascaded connection between LUT primitive 202 and LUT primitive 204 is not available. Accordingly, in FIG. 2, connection 210 is routed using conventional routing resources external to the respective slices that link the different slices and/or CLBs of the target IC device. Connection 210 is substantially slower than a cascaded connection due, at least in part, to intervening programmable routing circuitry and/or switches (not shown) along connection 210. For example, connection 210 may have a delay range from approximately 120 picoseconds to approximately 150 picoseconds or more.

FIG. 3 illustrates example LUT circuitry that utilizes a cascaded connection within the target IC device in accordance with one or more embodiments of the disclosed technology. In the example of FIG. 3, a portion of the circuit design is technology mapped and placed into LUT primitive 302 and LUT primitive 304. Both LUT primitive 302 and LUT primitive 304 are disposed in a same slice 306. As such, a cascaded connection 308 is available to connect LUT primitive 302 and LUT primitive 304, which form a cascaded LUT circuit structure. In the example, cascaded connection 308 is within slice 306 and does not utilize routing resources external to slice 306. Cascaded connection lacks or omits switching circuitry typically used to route signals external to slice 306. In this regard, cascaded connection 308 is said to directly connect LUT primitive 302 with LUT primitive 304. Cascaded connection 308 may have an interconnect delay as low as 19 picoseconds, providing markedly improved performance relative to the example of FIG. 2.

In one or more embodiments, cascaded LUT circuit structures may be realized through a process that increases the amount or number of cuts of the circuit design that may be mapped and/or placed into a cascaded LUT circuit structure. As described in greater detail hereinbelow, one aspect of such a process permits the creation of cuts of the circuit design that have more inputs than inputs of a single LUT primitive available on the target IC device. As an illustrative and non-limiting example, a LUT primitive available on the target IC device may have “k” inputs. Accordingly, the cut enumeration and/or merging process may allow the generation of cuts with k or more inputs. For purposes of this example, the k-input LUT may be a LUT primitive available on the target IC device with the largest number of inputs. Further aspects of technology mapping and/or placement that leverage the usage of cascaded LUT circuit structures is described in greater detail hereinbelow.

It should be appreciated that the examples of FIGS. 1, 2, and 3 are provided for purposes of illustration and not limitation. Other types of IC devices may have different cascaded LUT circuit structures with different restrictions as to usage, different architectures, and the like. Further, the LUT primitives themselves may differ from the example of FIG. 1. For example, the LUT primitives may have a different number of inputs and/or outputs and/or allow different ones of the output signals to be used as cascaded connections to another LUT primitive. The inventive arrangements may be adapted to such other types of IC devices to leverage any cascaded LUT circuit structures included within such devices.

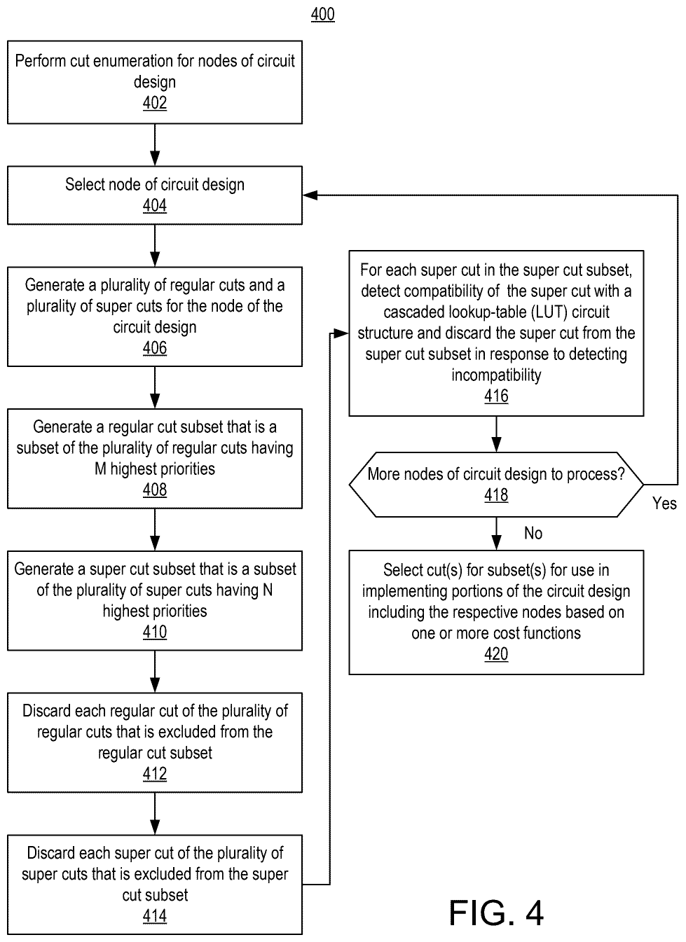

FIG. 4 illustrates a method 400 of processing a circuit design for implementation in a target IC device in accordance with one or more embodiments of the disclosed technology. Method 400 is an example of a computer-implemented method of technology mapping a circuit design for implementation in a target IC device that leverages the usage of cascaded LUT circuit structures of the target IC device. In general, method 400 seeks to increase choice of cuts for a given node of the circuit design. The increased choice in cut will include a variety of different cut types including types amenable to implementation using a cascaded LUT circuit structure.

In general, method 400 illustrates the handling of both regular cuts and super cuts. Regular cuts are smaller cuts. In cases where a six input LUT is used (e.g., k=6), a regular cut may have two to six inputs and may be mapped onto a single LUT primitive. A super cut is a larger cut having more than six inputs and may be mapped onto a cascaded LUT circuit structure (e.g., of two or more LUT primitives). Method 400 further illustrates how storage of cuts may be managed efficiently in a computer-based system while accommodating both types of cuts for large circuit designs to keep runtime manageable (e.g., low) while improving QoR.

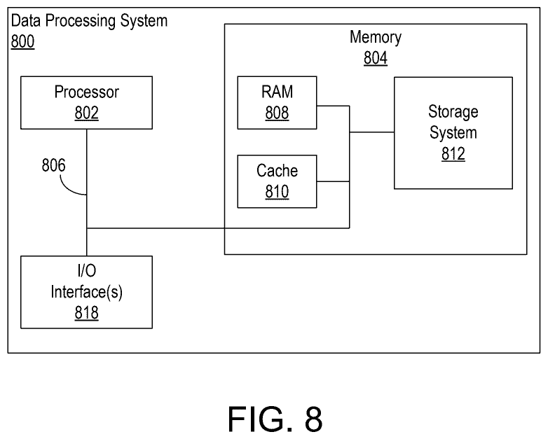

The operations described in connection with FIG. 4 may be performed by a data processing system executing suitable program code. For example, the data processing system may execute program code embodied as one or more Electronic Design Automation (EDA) tool(s). The EDA tool, or tools, may perform various aspects of a design flow. The design flow may include, synthesis, technology mapping, placement, routing, and/or configuration data generation. An example of a data processing system that is capable of performing the operations described within this disclosure (e.g., FIG. 4) is described in connection with FIG. 8.

Method 400 may begin in a state where a circuit design has undergone a portion of a design flow such as synthesis such that the circuit design exists in a technology independent state. Method 400 illustrates example operations for technology mapping the circuit design for implementation in a particular IC device referred to as the target IC device. In this regard, method 400 may be performed prior to other stages of the design flow such as placement, routing, and/or configuration data generation.

In block 402, the system is capable of performing cut enumeration for nodes of the circuit design. As noted, the circuit design has been synthesized and exists in a technology independent state. Often the circuit design at this stage is expressed as a graph of logic gates. Cut enumeration, as performed by the system, refers to the well-known process of identifying all possible subgraphs, or “cuts,” of a node in the circuit design that may be implemented using the available primitives of the target IC device. Each cut defines a boundary between the inputs and the internal logic that will be implemented in a specific manner using the available primitives. Cut enumeration is capable of generating multiple options for how different nodes and/or regions of a circuit design may be physically realized in the target IC device. In practice, the number of cuts generated per node in the circuit design may be limited by an upper threshold or maximum so that runtime of the system in processing the circuit design is balanced with QoR. Generating and storing too many cuts per node may require such a large amount of runtime memory (e.g., random-access-memory) that runtime of the system becomes too slow to be usable.

The system is further capable of implementing a process by which cuts may be merged. In block 404, the system is capable of selecting a node of the circuit design. In block 406, the system is capable of generating a plurality of regular cuts and a plurality of super cuts for the node selected in block 404. In generating the regular cuts and the super cuts for the node, the system is capable of performing one or more merge operations. A merge operation is an operation performed by the system that combines two or more cuts of the circuit design to form a larger cut.

In conventional approaches, cuts having a number of inputs of k or less, where k is the number of inputs that a k-LUT primitive can accept, were permitted. As noted, cuts with k inputs or less are referred to as “regular cuts.” Cuts that had a number of inputs exceeding k were rejected in conventional technology mapping techniques. More particularly, if the system detected that a merge operation would generate a cut with more than k inputs, the merge operation was not performed and the cut was not generated. To better utilize cascaded LUT circuit structures, however, cuts with a number of inputs exceeding k are generated and also accepted as permissible cuts for the circuit design. Cuts with a number of inputs exceeding k are referred to as “super cuts.”

In one or more embodiments, the system is capable of imposing a predetermined upper threshold that specifies a maximum number of inputs permissible for a super cut. The number of LUT primitives that may be cascaded to form a cascaded LUT circuit structure may be used to establish the predetermined upper threshold number of inputs permissible on a super cut. As an illustrative and non-limiting example, the predetermined upper threshold may be expressed as X*k−(X−1), where X is the number of LUT primitives that may be cascaded to form a cascaded LUT circuit structure and k is the number of inputs of the LUT primitives to be cascaded. Thus, in the case of a cascaded LUT circuit structure having three LUT primitives each with six inputs, the upper limit on the number of inputs for a super cut is 16. For purposes of illustration within this disclosure, cascaded LUT circuit structures having two LUT primitives each with six inputs are used such that the predetermined upper threshold is 11. It should be appreciated that other upper limits may be suitable depending on the particular architecture of the target IC device including the particular circuit architecture of the LUT primitives that are cascaded.

In one or more embodiments, in generating the plurality of regular cuts and the plurality of super cuts, each different cut type may be maintained and stored in memory device of the system in a separate list for the node. For example, for a given node (e.g., each node of the circuit design processed), a super cut list may be generated and stored the memory device. The super cut list includes or specifies each super cut of the plurality of super cuts for the node. Similarly, for the given node, a regular cut list that is separate and distinct from the super cut list may be generated and stored in the memory device. The regular cut list includes or specifies each regular cut of the plurality of regular cuts for the node.

In block 408, the system is capable of generating a regular cut subset that is a subset of the plurality of regular cuts having M highest priorities. In one or more embodiments, the system is capable of calculating a priority for each regular cut in the list of regular cuts. The system may calculate the priorities using a priority function. The system is capable of selecting M regular cuts that have the highest M priorities, where M is an integer value of two or more. In one or more examples, M may be set to a value such as 30, 40.

In one or more example implementations, the priority function for a regular cut may be calculated based on an estimation of the delay of the regular cut and/or a number of input pins of the regular cut. The system is capable of sorting regular cuts based on delay such that the regular cut with the lowest delay is ranked highest and the regular cut with the largest delay is ranked lowest. As such, regular cuts with lower delays are prioritized higher than regular cuts with higher delays. For those regular cuts that have a same delay, the regular cut with the fewest inputs is prioritized above the regular cut with more inputs. The system includes within the regular cut subset the top M regular cuts sorted using the priority function as described. That is, the M highest priority regular cuts are included in the regular cut subset with the other regular cuts of the plurality of regular cuts being excluded from the regular cut subset.

In block 410, the system is capable of generating a super cut subset that is a subset of the plurality of super cuts having N highest priorities. The system is capable of selecting N super cuts that have the highest N priorities, where N is an integer value of two or more. The system may calculate the priorities using a priority function.

In one or more embodiments, the system is capable of performing the same sorting using the same prioritization function for the plurality of super cuts as performed for the plurality of regular cuts. That is, the system uses a common priority function (e.g., the same priority function) to prioritize the regular cuts and the super cuts to determine the top M and top N cuts in the respective lists. The system includes within the super cut subset the top N super cuts sorted as described. That is, the N highest priority super cuts are included in the super cut subset with the other super cuts of the plurality of super cuts being excluded from the super cut subset. Appreciably, in the example of FIG. 4, the prioritization and sorting for the regular cut list and for the super cut list is performed independently.

In the example, the number of items included in each respective subset may be different. That is, M may not be equal to N. In one or more embodiments, M may be greater than N. As an illustrative and non-limiting example, N may be set to approximately 8, 9, or 10, while M is set to approximately 30 or 40. In general, the number of regular cuts preserved in the regular cut subset (e.g., M) may be set to a lower value than would be the case in conventional techniques that do not form or preserve super cuts. If the number of regular cuts were allowed to grow larger, the system may create too many super cuts for subsequent logic nodes/levels thereby imposing a computational burden on the system by consuming too much runtime memory.

In block 412, the system is capable of discarding each regular cut of the plurality of regular cuts that is excluded from the regular cut subset. In block 414, the system is capable of discarding each super cut of the plurality of super cuts that is excluded from the super cut subset. The operations of blocks 412 and 414 effectively prune the respective lists. Initially, the plurality of regular cuts and the plurality of super cuts are all stored in the memory device of the system, e.g., a runtime memory such as random-access memory (RAM). Any cuts, whether regular cuts or super cuts, that are discarded are removed or deleted from memory device of the system. Once removed or discarded, such cuts are no longer stored in runtime memory of the system (e.g., are deleted and do not occupy computational resources).

Accordingly, post discarding, the regular cut list includes only those regular cuts in the regular cut subset. Post discarding, the super cut list includes only those super cuts in the super cut subset. Pruning the regular cuts as described to M regular cuts reduces the number of super cuts that may be created for the next node. As observed, the pruning (e.g., prioritizing and discarding) is performed separately and independently for the regular cuts and the super cuts for a node. Keeping the number of super cuts limited and pruning the number of super cuts reduces the amount of runtime memory needed by the system to implement method 400 (e.g., increases the computational efficiency of method 400), which in turn reduces runtime of the overall process of FIG. 4. In general, the pruning process described balances the QoR achieved for the circuit design implementation with the runtime of the system that would otherwise become unmanageably large for reasonable runtimes.

In block 416, for each super cut in the super cut subset, the system is capable of detecting compatibility of the super cut with a cascaded LUT circuit structure of the target IC device and discarding the super cut from the super cut subset in response to detecting incompatibility. The system is capable of testing each of the super cuts of the super cut subset for compatibility and discarding each incompatible super cut from the super cut subset. The discarding removes or deletes the super cut from the memory device (e.g., runtime memory) of the system.

In conventional technology mapping techniques, determining whether a given cut is compatible with a given circuit structure (e.g., that the cut “maps” onto the circuit structure), decomposition techniques are performed. Decomposition generally involves the use of Binary Decision Diagrams (BDDs), Satisfiability (SAT) solvers, or truth tables to manipulate Boolean logic of the circuit design. Such techniques are computationally intensive and often consume significant runtime.

In accordance with the inventive arrangements described herein, the system is capable of detecting compatibility of a super cut for a given cascaded LUT circuit structure by traversing the cut structure of the circuit design that exists. The system is capable of traversing the cut structure of a super cut, for example, to detect certain cuts therein having predefined signatures and predefined connectivity that maps onto constituent LUT primitives of a cascaded LUT circuit structure. Traversing the cut structure to detect compatibility may be performed faster, e.g., with less runtime, than decomposition-based techniques.

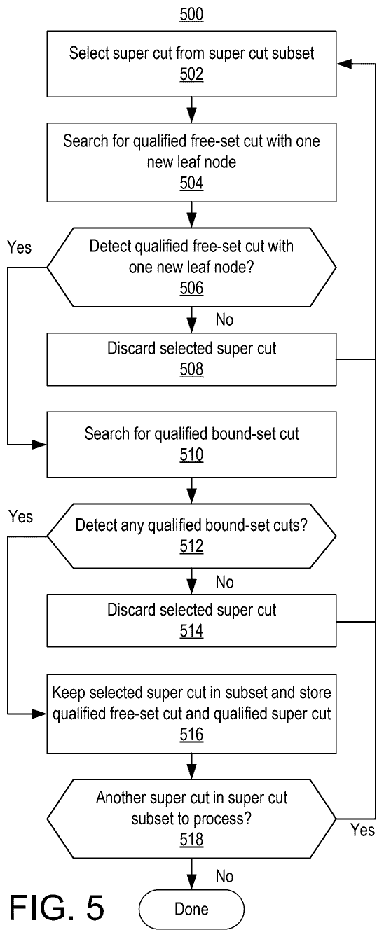

In one or more embodiments, the system is capable of detecting compatibility of each super cut by detecting that a qualified free-set cut having a new leaf and a qualified bound-set cut exists for the super cut. The new leaf corresponds to a cascade input of the cascaded LUT circuit structure. For each of the super cuts that are determined to be compatible, as part of block 414, the system is capable of storing the qualified free-set cut and the qualified bound-set cut with the super cut. Further details relating to the implementation of block 414 are described in connection with FIG. 5 below.

In block 418, the system is capable of detecting whether there are any further nodes of the circuit design to process. The system is capable of processing the nodes of the circuit design in a topological order, e.g., from input to output. In response to detecting one or more nodes of the circuit design to process, method 400 loops back to block 404 to select another node and continue processing. In response to detecting that no further nodes of the circuit design remain to be processed, method 400 continues to block 420.

In block 420, the system is capable of selecting cut(s) from subset(s), e.g., a group of cuts, for use in implementing portions of the circuit design including the respective nodes based on one or more cost functions. For example, having emerged from the process by which regular subsets (e.g., lists of regular cuts) and super cut subsets (e.g., lists of super cuts) are generated for nodes of the circuit design, there are a variety of different implementation options available for the nodes that include both regular cuts and super cuts. The implementation options for a given node of the circuit design, e.g., each node, can include both regular cuts and super cuts. The system is capable of selecting a cut to be used for each node (e.g., the root node) that is used to technology map the cut to one or more components (e.g., primitives) of the target device. Appreciably, those cuts that are super cuts may be technology mapped to cascaded LUT circuit structures. The increase in cut options increases the likelihood that a super cut will be selected thereby increasing the usage of cascaded LUT circuit structures. As generally known, there is a strong if not direct link between the selected cut(s) and the final timing of the circuit design as realized in the target IC device.

In one or more embodiments, a cost function may be used to select the cuts for use in technology mapping and for placement. The cost function may consider parameters for cuts such as delay, area, pin density, and the like. In one or more embodiments, the cost function may be implemented as a weighted sum of the aforementioned parameters (e.g., a(delay)+b(area)+c(pin density) where a, b, and c are weights between 0 and 1). In one or more embodiments, a different cost function may be used for the regular cuts than is used for the super cuts. As an illustrative example, the weighting of one or more of the parameters may differ between the two cost functions.

For purposes of illustration, consider the case of a super cut. When calculating the cost of a super cut, the delay used will be the delay as if the super cut were implemented using a cascaded LUT circuit structure rather than as LUT circuitry that does not utilize a cascaded connection. This may result in weighting the timing of each node of the cut corresponding to the LUT differently to achieve a total delay that more accurately reflects the delay of a cascaded LUT circuit structure rather than LUT circuitry that is not cascaded.

For ease of illustration, consider an example in which the delay of a super cut that maps onto a two-LUT cascaded LUT circuit structure will be 1.2 as opposed to 2 for a cut that maps onto two non-cascaded LUT primitives. In this example, the weighting factor for the delay may be less than 1, while the weighting factor for delay of a cut mapped onto two non-cascaded LUT primitives may be 1. Similarly, area may be weighted differently for regular cuts and super cuts. The system may set the area of a two-LUT cascaded LUT circuit structure to 1.5 instead of 2, whereas a cut mapped onto two non-cascaded LUT primitives would be 2.

For purposes of illustration, consider pin density. The system may weight two regular non-cascaded LUT primitives according to the expression a+b−1, where a and b are number of input pins on each respective LUT primitive. For cascaded LUT primitives, more weight can be given because the system understands that those two LUT primitives are put into a single slice and, as such, will be more likely to cause congestion if over-used. In that case, the system may set the weight according to the expression 2*(a+b−1), for example.

In implementing block 420, the system is capable of performing one or more other operations that may include, but are not limited to, a depth-driven optimization pass (to reduce depth or number of levels of combinatorial logic), optionally an area-driven pass (to reduce estimated area consumption of the cuts), and/or optionally an area recovery pass. The aforementioned operations that may be included in the optimization pass are generally known techniques in the field that may be performed after cut enumeration to provide different area costing/weights for each candidate cut on nodes. For example, an area optimization pass generally refers to a forward propagation of cost/weights that considers area as target optimization. Area-recovery generally refers to a post-processing operation performed after cuts are selected for each nodes to re-select cuts for some nodes to further optimize area.

In one or more embodiments, one or more or all of these operations in reference to the depth-driven pass, the area-driven pass, and the area recovery pass may be performed for the super cuts.

For selected cuts that are super cuts, such cuts are technology mapped to cascaded LUT circuit structures. Subsequent to performing the technology mapping, the system is capable of performing other operations of a design flow to physically realize the circuit design within the target IC device. For example, the system is capable of placing and routing the circuit design. The system is also capable of generating configuration data that, when loaded into the target IC device, physically realizes the circuit design, as placed and routed, within the target IC device.

FIG. 5 illustrates a method 500 of detecting compatibility of a super cut with a cascaded LUT circuit structure in accordance with one or more embodiments of the disclosed technology. Method 500 may implement block 414 of FIG. 4. As discussed, in implementing method 500, the system is capable of traversing super cuts to detect certain cut signatures therein that may be mapped onto cascaded LUT circuit structures. Accordingly, method 500 may begin in a state where a particular super cut subset is being processed.

In block 502, the system selects a super cut from the super cut subset. In block 504, the system searches for a qualified free-set cut with one new leaf node. For example, the system traverses the super cut to detect a qualified free-set cut with one new leaf node.

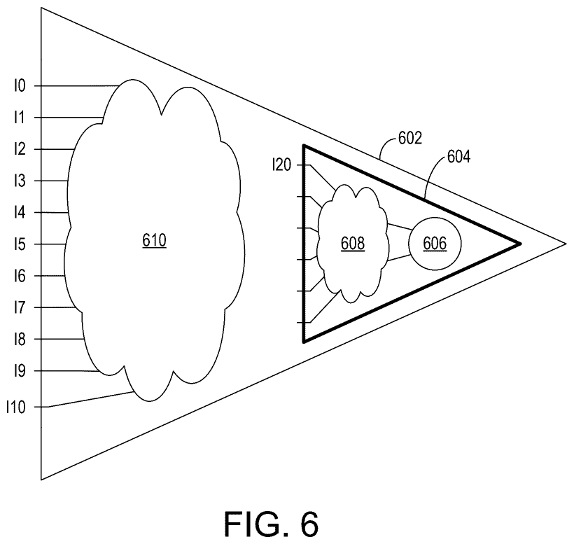

FIG. 6 illustrates a super cut 602 including a qualified free-set cut 604 in accordance with one or more embodiments of the disclosed technology. Super cut 602 includes a root node 606. Root node 606 is coupled to further nodes represented as nodes 608, which in turn is connected to further nodes illustrated as nodes 610. In the example, the system has traversed the cuts, e.g., the cut structure, of super cut 602 and detected a qualified free-set cut 604.

A qualified free-set cut is a regular cut, e.g., a cut having k or fewer inputs, that has one and only one additional leaf (e.g., input) node that does not exist in the original super cut. The new leaf node will be used as the root node in finding or detecting the qualified bound-set cut. Because the leaf node appears earlier in topological order, the regular cuts of the leaf node should have already been generated and stored.

Qualified free-set cut 604 includes a new leaf node illustrated as input I20 in FIG. 6. A new leaf node refers to an input of the qualified free-set cut that is not an input of the super cut containing the qualified free-set cut. In the example of FIG. 6, super cut 602 includes inputs I0, I1, I2, I3, I4, I5, I6, I7, I8, I9, and I10 (e.g., 11 inputs corresponding to the maximum number of inputs that may be included in a super cut that is to be mapped onto a two-LUT cascaded LUT circuit structure. Input I20 of qualified free-set cut 604 is not a member of the inputs of super cut 602.

In block 506, in response to detecting no qualified free-set cut with one new leaf node, method 500 continues to block 508, where the selected super cut is discarded. In this situation, the super cut is considered incompatible with the cascaded LUT circuit structure. The super cut being evaluated is removed from the memory device (e.g., deleted) thereby freeing up memory resources. In response to detecting a qualified free-set cut with one new leaf node, method 500 continues to block 510.

In block 510, the system searches for qualified bound-set cut. For example, the system traverses the super cut to detect a qualified bound-set cut. The system is capable of traversing from the new leaf node of the qualified free-set cut to find another regular cut that may be used as the bound-set cut. A qualified bound-set cut is a cut that complements the qualified free-set cut to include the rest of the leaf nodes from the original super cut. A union of the leaf nodes from bound-set and free-set cut, excluding the new leaf node, will equal the leaf nodes of the super cut.

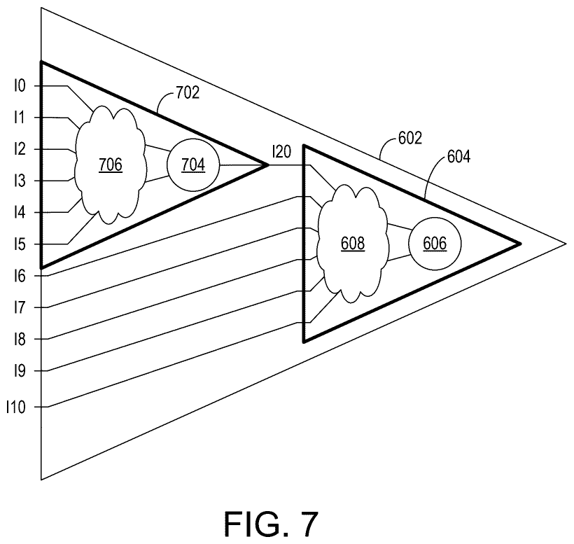

FIG. 7 illustrates super cut 602 including qualified free-set cut 604 and a qualified bound-set cut 702 in accordance with one or more embodiments of the disclosed technology. As illustrated qualified bound-set cut 702 is a regular cut having a root node 704 reached from input I20 of qualified free-set cut 604. To be considered a qualified bound-set cut, the regular cut has a root node directly connected (e.g., without any intervening elements) to the new leaf node and each input of the regular cut is an input of the super cut. In the example of FIG. 7, root node 704 is connected to input I20, which is the new leaf node. Root node 704 is coupled to inputs input I0, I1, I2, I3, I4, and I5 of qualified bound-set cut 702. Further, each of inputs I0, I1, I2, I3, I4, and I5 of qualified bound-set cut 702 is an input of super cut 602.

The other leaf nodes I6, I7, I8, I9, and I10 of super cut 602 (e.g., the leaf nodes of super cut 602 excluded from qualified bound-set cut 702) must connect directly to the boundary of qualified free-cut set 604 in order to meet the requirement that the union of bound-set cut 702 and qualified free-set cut 604 minus the new leaf node (e.g., I20) will include, or be equivalent to, the set of all leaf nodes of original super cut 602. In other words, the union of the inputs of qualified free-set cut 604, excluding the new leaf node, and qualified bound-set cut 702 should be equivalent to the inputs of super cut 602. If any of inputs I6-I10 are not directly connected to the boundary of qualified free-cut set 604 or included as part of the leaf nodes of qualified free-cut set 604, then the two smaller, inner cuts (e.g., 604, 702) may not be used to create a cascaded LUT circuit structure and the method will move on to try more combinations. Though not illustrated in the example of FIG. 7, in some cases, leaf nodes of the bound-set cut and leaf nodes of the free-set cut may overlap. For example, both the leaf nodes of the bound-set cut and the leaf nodes of the free-set cut may include I4.

In block 512, in response to detecting no qualified bound-set cuts, method 500 continues to block 514, where the selected super cut is discarded. In this situation, the super cut is considered incompatible with the cascaded LUT circuit structure. The super cut being evaluated is removed from the memory device (e.g., deleted) thereby freeing up memory resources. In response to detecting a qualified bound-set cut, method 500 continues to block 516.

In block 516, the system keeps the selected super cut within the super cut subset. Further, the system is capable of storing the qualified free-set cut and the qualified super cut with, or in association with, the super cut of the super cut subset.

Referring to the examples of FIGS. 3 and 7, qualified bound-set cut 702 may be mapped onto LUT primitive 302. Qualified free-set cut 604 may be mapped onto LUT primitive 304. The free leaf node corresponding to I20 may be mapped onto cascaded connection 308.

In block 518, the system is capable of detecting whether there are any further super cuts in the super cut subset to process. In response to detecting one or more super cuts in the super cut subset to process, method 500 loops back to block 502 to select another super cut of the super cut subset and continue processing. In response to detecting that no further super cuts of the super cut subset remain to be processed, method 500 may end. In the context of FIG. 4, the method may continue to block 416.

FIG. 8 illustrates an example implementation of a data processing system 800. As defined herein, the term “data processing system” means one or more hardware systems configured to process data, each hardware system including at least one processor and memory, wherein the processor is programmed with computer-readable program instructions that, upon execution, initiate operations. Data processing system 800 can include a processor 802, a memory 804, and a bus 806 that couples various system components including memory 804 to processor 802.

Processor 802 may be implemented as one or more processors. In an example, processor 802 is implemented as a hardware processor such as a central processing unit (CPU). Processor 802 may be implemented as one or more circuits capable of carrying out instructions contained in program code. The circuit(s) may be an IC or embedded in an IC. Processor 802 may be implemented using a complex instruction set computer architecture (CISC), a reduced instruction set computer architecture (RISC), a vector processing architecture, or other known architectures. Example processors include, but are not limited to, processors having an x86 type of architecture (IA-32, IA-64, etc.), Power Architecture, ARM processors, and the like.

Bus 806 represents one or more of any of a variety of communication bus structures. By way of example, and not limitation, bus 806 may be implemented as a Peripheral Component Interconnect Express (PCIe) bus. Data processing system 800 typically includes a variety of computer system readable media. Such media may include computer-readable volatile and non-volatile media and computer-readable removable and non-removable media.

Memory 804 can include computer-readable media in the form of volatile memory, such as random-access memory (RAM) 808 and/or cache memory 810. Data processing system 800 also can include other removable/non-removable, volatile/non-volatile computer storage media. By way of example, storage system 812 can be provided for reading from and writing to a non-removable, non-volatile magnetic and/or solid-state media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 806 by one or more data media interfaces. Memory 804 is an example of at least one computer program product.

Memory 804 is capable of storing program code that is executable by processor 802 to cause processor 802 to perform operations (e.g., executable operations). For example, the program code can include an operating system, one or more application programs, other program code, and program data. Processor 802, in executing the program code, is capable of performing the various operations described herein that are attributable to a computer. In one or more examples, the program code may include or implement one or more EDA tools, e.g., program code, capable of performing an implementation flow on a circuit design (e.g., synthesis, technology mapping, placement, routing, and/or configuration data generation).

It should be appreciated that data items used, generated, and/or operated upon by data processing system 800 are functional data structures that impart functionality when employed by data processing system 800. As defined within this disclosure, the term “data structure” means a physical implementation of a data model's organization of data within a physical memory. As such, a data structure is formed of specific electrical or magnetic structural elements in a physical memory such as a memory device (e.g., memory 804 or components thereof). A data structure imposes physical organization on the data stored in the memory device as used by an application program executed using a processor.

Data processing system 800 may include one or more Input/Output (I/O) interfaces 818 communicatively linked to bus 806. I/O interface(s) 818 allow data processing system 800 to communicate with one or more external devices and/or communicate over one or more networks such as a local area network (LAN), a wide area network (WAN), and/or a public network (e.g., the Internet). Examples of I/O interfaces 818 may include, but are not limited to, network cards, modems, network adapters, hardware controllers, etc. Examples of external devices also may include devices that allow a user to interact with data processing system 800 (e.g., a display, a keyboard, and/or a pointing device) and/or other devices such as an accelerator card.

Data processing system 800 is only one example implementation. Data processing system 800 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

As used herein, the term “cloud computing” refers to a computing model that facilitates convenient, on-demand network access to a shared pool of configurable computing resources such as networks, servers, storage, applications, ICs (e.g., programmable ICs) and/or services. These computing resources may be rapidly provisioned and released with minimal management effort or service provider interaction. Cloud computing promotes availability and may be characterized by on-demand self-service, broad network access, resource pooling, rapid elasticity, and measured service.

The example of FIG. 8 is not intended to suggest any limitation as to the scope of use or functionality of example implementations described herein. Data processing system 800 is an example of computer hardware that is capable of performing the various operations described within this disclosure. In this regard, data processing system 800 may include fewer components than shown or additional components not illustrated in FIG. 8 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular embodiments only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the term “approximately” means nearly correct or exact, close in value or amount but not precise. For example, the term “approximately” may mean that the recited characteristic, parameter, or value is within a predetermined amount of the exact characteristic, parameter, or value.

As defined herein, the terms “at least one,” “one or more,” and “and/or,” are open-ended expressions that are both conjunctive and disjunctive in operation unless explicitly stated otherwise.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums. A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, the phrase “in response to” and the phrase “responsive to” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the term “user”refers to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the terms “one embodiment,” “an embodiment,” “in one or more embodiments,” “in particular embodiments,” or similar language mean that a particular feature, structure, or characteristic described in connection with the embodiment is included in at least one embodiment described within this disclosure.

Thus, appearances of the aforementioned phrases and/or similar language throughout this disclosure may, but do not necessarily, all refer to the same embodiment.

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the inventive arrangements described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored therein comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various embodiments of the disclosed technology have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method of technology mapping a circuit design, the method comprising:
generating, by computer hardware, a plurality of regular cuts and a plurality of super cuts for a node of a circuit design;
generating, by the computer hardware, a regular cut subset that is a subset of the plurality of regular cuts having M highest priorities and a super cut subset that is a subset of the plurality of super cuts having N highest priorities;
discarding, by the computer hardware, from the super cut subset each super cut that is incompatible with a cascaded lookup-table (LUT) circuit structure; and
selecting a cut from a group of cuts including the regular cut subset and the super cut subset to implement a portion of the circuit design including the node.

2. The computer-implemented method of claim 1, wherein the regular cut subset and the super cut subset are generated using a common priority function.

3. The computer-implemented method of claim 1, wherein each super cut has a number of inputs exceeding a number of inputs of a single LUT primitive of a target integrated circuit device.

4. The computer-implemented method of claim 3, wherein the number of inputs of each super cut is less than a predetermined upper threshold number of inputs.

5. The computer-implemented method of claim 1, wherein the plurality of regular cuts and the plurality of super cuts are stored in a memory device, and wherein the method further comprises:
discarding each regular cut of the plurality of regular cuts that is excluded from the regular cut subset from the memory device and each super cut of the plurality of super cuts that is excluded from the super cut subset from the memory device.

6. The computer-implemented method of claim 5, wherein each incompatible super cut is deleted from the memory device.

7. The computer-implemented method of claim 1, further comprising:
detecting compatibility of each super cut of the super cut subset by detecting whether the super cut includes a qualified free-set cut having a new leaf and a qualified bound-set cut.

8. The computer-implemented method of claim 7, wherein the new leaf corresponds to a cascade input of the cascaded LUT circuit structure.

9. The computer-implemented method of claim 7, further comprising:
storing the qualified free-set cut and the qualified bound-set cut with the super cut.

10. A system, comprising:
a memory capable of storing program instructions; and
a hardware processor capable of performing operations for mapping a circuit design in response to execution of the program instructions, the operations including:
generating a plurality of regular cuts and a plurality of super cuts for a node of a circuit design;
generating a regular cut subset that is a subset of the plurality of regular cuts having M highest priorities and a super cut subset that is a subset of the plurality of super cuts having N highest priorities;
discarding from the super cut subset each super cut that is incompatible with a cascaded lookup-table (LUT) circuit structure; and
selecting a cut from a group of cuts including the regular cut subset and the super cut subset to implement a portion of the circuit design including the node.

11. The system of claim 10, wherein the regular cut subset and the super cut subset are generated using a common priority function.

12. The system of claim 10, wherein each super cut has a number of inputs exceeding a number of inputs of a single LUT primitive of a target integrated circuit device.

13. The system of claim 12, wherein the number of inputs of each super cut is less than a predetermined upper threshold number of inputs.

14. The system of claim 10, wherein the plurality of regular cuts and the plurality of super cuts are stored in a memory device, and wherein the hardware processor capable of performing further operations comprising:
discarding each regular cut of the plurality of regular cuts that is excluded from the regular cut subset from the memory device and each super cut of the plurality of super cuts that is excluded from the super cut subset from the memory device.

15. The system of claim 14, wherein each incompatible super cut is deleted from the memory device.

16. The system of claim 10, wherein the hardware processor capable of performing further operations comprising:
detecting compatibility of each super cut of the super cut subset by detecting whether the super cut includes a qualified free-set cut having a new leaf and a qualified bound-set cut.

17. The system of claim 16, wherein the new leaf corresponds to a cascade input of the cascaded LUT circuit structure.

18. The system of claim 16, wherein the hardware processor capable of performing further operations comprising:
storing the qualified free-set cut and the qualified bound-set cut with the super cut.

19. A computer program product comprising a computer readable storage medium having program instructions embodied therewith, wherein the program instructions are executable by computer hardware to cause the computer hardware to initiate executable operations comprising:
generating a plurality of regular cuts and a plurality of super cuts for a node of a circuit design;
generating a regular cut subset that is a subset of the plurality of regular cuts having M highest priorities and a super cut subset that is a subset of the plurality of super cuts having N highest priorities;
discarding from the super cut subset each super cut that is incompatible with a cascaded lookup-table (LUT) circuit structure; and
selecting a cut from a group of cuts including the regular cut subset and the super cut subset to implement a portion of the circuit design including the node.

20. The computer program product of claim 19, wherein each super cut has a number of inputs exceeding a number of inputs of a single LUT primitive of a target integrated circuit device.
